(19) United States
(12) Patent Application Publication
(10) Pub. No.: US 2018/0130867 A1
(43) Pub. Date: May 10, 2018

(54) MAGNETIC ISOLATORS FOR INCREASED VOLTAGE OPERATIONS AND RELATED METHODS

(71) Applicant: Analog Devices Global, Hamilton (BM)

(72) Inventors: Paul Lambkin, Carrigaline (IE); Michal J. Osiak, Castletroy (IE); Brian Anthony Moane, Raheen (IE); Stephen O'Brien, Clarina (IE); Laurence Brendan O'Sullivan, Limerick (IE); Patrick J. Murphy, Patrickswell (IE); Patrick M. McGuinness, Limerick (IE); Bernard P. Stenson, Limerick (IE)

(21) Appl. No.: 15/347,724

(22) Filed: Nov. 9, 2016

(51) Int. Cl. H01L 49/02; H01F 27/28; H01F 41/04

(52) U.S. Cl. CPC H01L 28/10; H01F 2027/2809; H01F 41/041; H01F 27/2804

(57) ABSTRACT

A magnetic isolator is described. The magnetic isolator may comprise a top conductive coil, a bottom conductive coil, and a dielectric layer separating the top conductive coil from the bottom conductive coil. The top conductive coil may comprise an outermost portion having multiple segments. The segments may be configured to reduce the peak electric field in a region of the dielectric layer near the outer edge of the top conductive coil. The top conductive coil may comprise a first lateral segment, and a second lateral segment that is laterally offset with respect to the first lateral segment. The first lateral segment may be closer to the center of the top conductive coil than the second lateral segment, and may be closer to the bottom conductive coil than the second lateral segment. The magnetic isolator may be formed using microfabrication techniques.

### FIELD OF DISCLOSURE

The present application relates to microfabricated magnetic isolators.

### BACKGROUND

Some magnetic isolators include a primary winding and a secondary winding. Typically, a signal is provided to the primary winding of the isolator, and is coupled via magnetic induction to the secondary winding.

### SUMMARY OF THE DISCLOSURE

According to some embodiments, a magnetic isolator is described. The magnetic isolator may comprise a top conductive coil, a bottom conductive coil, and a dielectric layer separating the top conductive coil from the bottom conductive coil. The top conductive coil may comprise an outermost portion having multiple segments. The segments may be configured to reduce the peak electric field in a region of the dielectric layer near the outer edge of the top conductive coil. The top conductive coil may comprise a first lateral segment, and a second lateral segment that is laterally offset with respect to the first lateral segment. The first lateral segment may be closer to the center of the top conductive coil than the second lateral segment, and may be closer to the bottom conductive coil than the second lateral segment. The magnetic isolator may be formed using microfabrication techniques.

According to one aspect of the present application, an apparatus is provided. The apparatus may comprise a first conductive coil, a second conductive coil, and a dielectric layer separating the first conductive coil from the second conductive coil, wherein the first conductive coil comprises an outermost portion having a non-planar bottom surface.

According to another aspect of the present application, an apparatus is provided. The apparatus may comprise a first conductive coil, a second conductive coil, a dielectric layer separating the first conductive coil from the second conductive coil, and a controller electrically coupled to the first conductive coil, wherein the first conductive coil comprises an outermost portion having a non-planar bottom surface.

According to yet another aspect of the present application, a method for fabricating an isolator is provided. The method may comprise forming a first metallization layer on a semiconductor substrate, and patterning the first metallization layer to obtain a first conductive coil, forming a dielectric layer on the semiconductor substrate to cover the first conductive coil, forming a dielectric ridge, and forming a second metallization layer on the dielectric layer, and patterning the second metallization layer to obtain a second conductive coil such that an outermost portion of the second conductive coil partially lies over the dielectric ridge.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1A is a cross sectional view illustrating a magnetic isolator, according to some non-limiting embodiments.

FIG. 1B is a perspective cutaway view illustrating a non-planar outermost portion of a conductive coil as may be used in an isolator, according to some non-limiting embodiments.

FIG. 1C is a cross sectional view illustrating an alternative implementation of a magnetic isolator, according to some non-limiting embodiments.

FIG. 1D is a top view illustrating a conductive coil as may be used in an isolator, according to some non-limiting embodiments.

FIG. 2 is a cross sectional view illustrating an alternative magnetic isolator to that of FIG. 1A, according to some non-limiting embodiments.

FIG. 3 is a flowchart illustrating a method for microfabricating a magnetic isolator, according to some non-limiting embodiments.

FIGS. 4A-4G are cross sectional views collectively illustrating a method for fabricating a magnetic isolator, according to some non-limiting embodiments.

FIG. 5 is a cross sectional view illustrating another magnetic isolator, according to some non-limiting embodiments.

FIG. 6A is a top view illustrating a photomask for forming a dielectric ridge, according to some non-limiting embodiments.

FIG. 6B is a top view illustrating another photomask for forming a dielectric ridge, according to some non-limiting embodiments.

FIG. 7 is a block diagram illustrating a system comprising a magnetic isolator, according to some non-limiting embodiments.

### DETAILED DESCRIPTION

Applicant has appreciated that for a microfabricated magnetic isolator having primary and secondary coils separated by a dielectric layer, the maximum voltage at which the magnetic isolator can be operated may be increased by reducing the probability of electric breakdown in the dielectric layer. Electric breakdown can occur when the local electric field within a dielectric material exceeds the material's breakdown electric field. When electric breakdown occurs, a conductive path is formed within the dielectric material. Such a conductive path may electrically short the primary and secondary coils of the isolator, thus preventing the magnetic isolator from providing the desired isolation. Applicant has appreciated that certain regions of the dielectric material are particularly susceptible to electric breakdown, due to a localized peak in the electric field. Such regions of large localized electric field may reside near the outer edge of a coil of the isolator.

According to one aspect of the present application, an outermost portion of a coil of a microfabricated magnetic isolator may be shaped in a manner which reduces the peak electric field near the edge of the coil. In this way, the probability of electric breakdown in the dielectric material may be reduced. In at least some embodiments the reduction may be significant. Consequently, an isolator exhibiting such a reduced peak electric field may withstand larger voltages, compared with conventional microfabricated magnetic isolators.

In some embodiments, the peak electric field may be reduced by shaping the outermost portion of a conductive coil to include first and second lateral segments coupled together but offset from one another. The structure may resemble a stair step in some embodiments. In this way, the peak electric field may be reduced and/or moved compared to conductive coils having a single, planar segment as an outermost portion. In some embodiments, the isolator may be used as an ISO coupler.

The aspects and embodiments described above, as well as additional aspects and embodiments, are described further below. These aspects and/or embodiments may be used individually, all together, or in any combination of two or more, as the application is not limited in this respect.

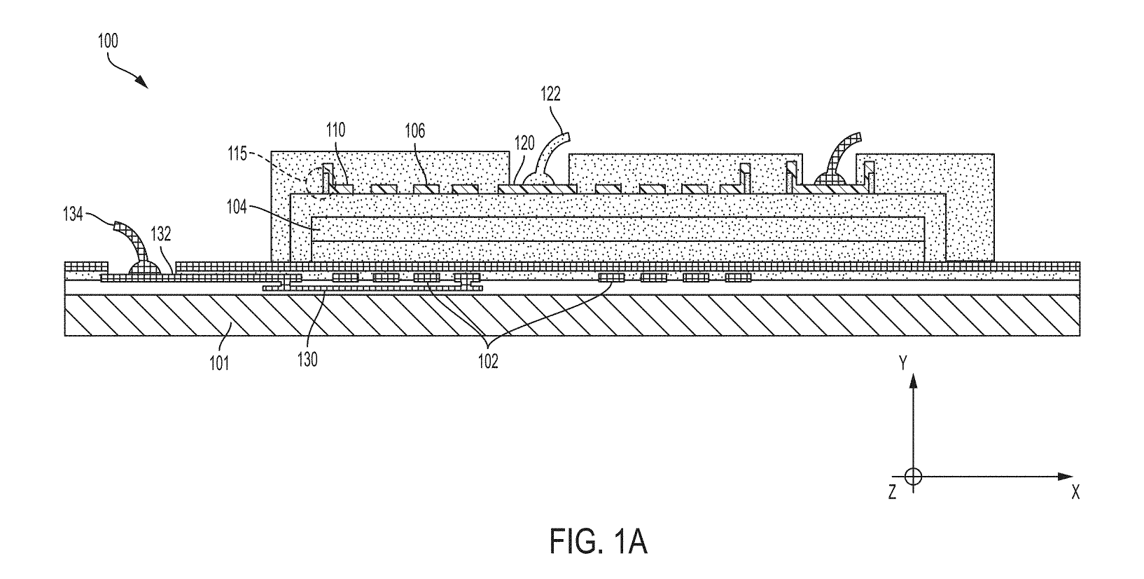

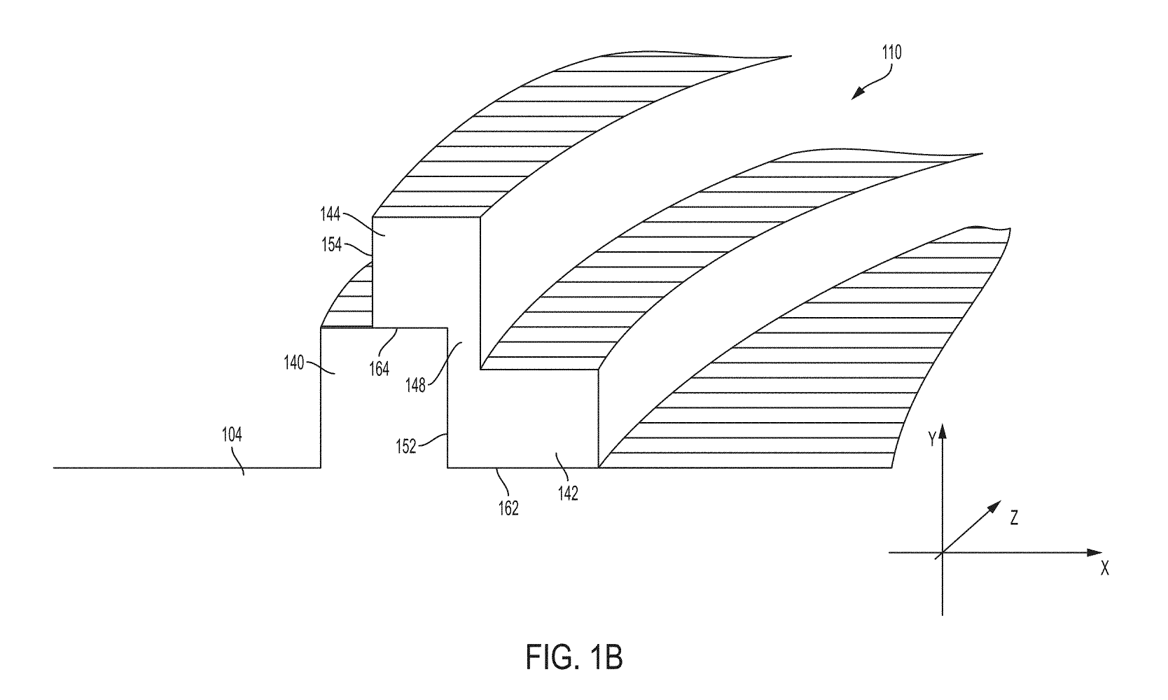

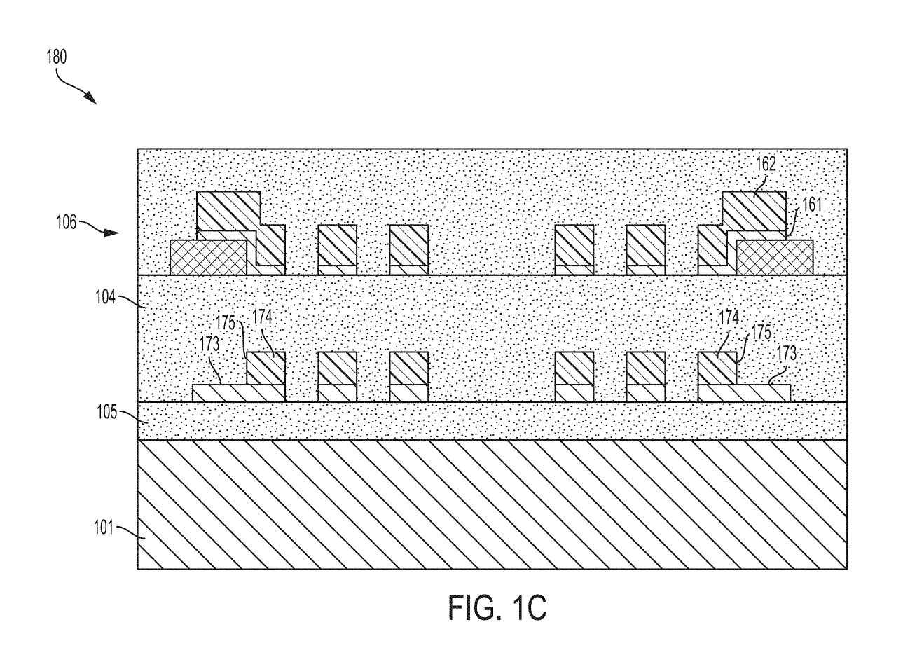

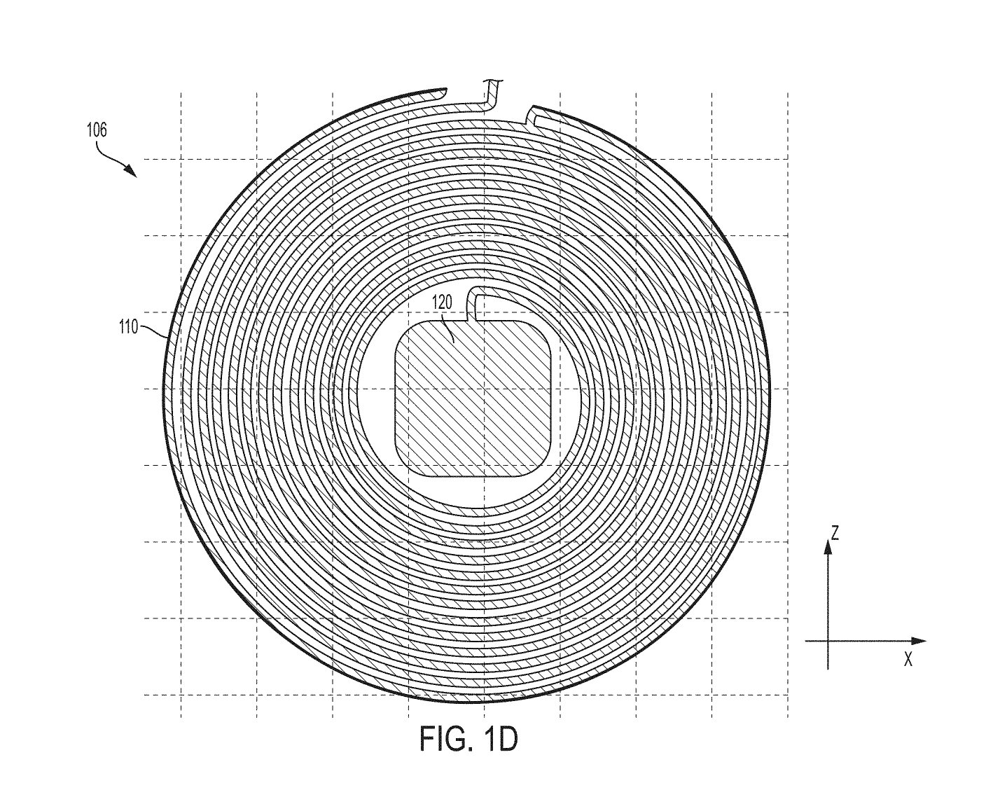

FIG. 1A illustrates a magnetic isolator, according to some non-limiting embodiments. Magnetic isolator 100, also referred to herein simply as an “isolator” or a “transformer”, may comprise a substrate 101, a bottom conductive coil 102, a dielectric layer 104, and a top conductive coil 106. In some embodiments, the top conductive coil may serve as the primary winding, and the bottom conductive coil may serve as the secondary winding. In other embodiments, the opposite configuration may be used.

The terms “bottom” and “top” are used herein to refer to the relative location of the conductive coils with respect to the substrate along the y-axis. In particular, the term bottom will be used to indicate the conductive coil that is closer to the substrate and the term top to indicate the conductive coil that is farther from the substrate. In some embodiments, substrate 101 may comprise a semiconductor substrate, such as a silicon substrate. However, other materials may be used.

Top conductive coil 106 may be formed on dielectric layer 104. Top conductive coil 106 may comprise one or more loops, and may be shaped as a spiral or according to any other suitable configuration. In some embodiments, the loops may be connected to each other, thus forming a continuous winding. Top conductive coil 106 may comprise any suitable conductive material, such as aluminum, copper, gold, silver, or chromium. During operation of magnetic isolator 100, an alternating current (AC) signal may be applied to a conductive coil (either the top or the bottom conductive coil), and an AC electric current may flow in the conductive coil. Consequently, a magnetic field may be generated. The generated magnetic field may have a component along the y-axis, and may be coupled to the opposite conductive coil, thus giving rise to an AC electromotive force in the opposite conductive coil. In this way, the AC signal may be coupled between the conductive coils, while at the same time direct current (DC) signals may be blocked via galvanic isolation. The ability to block DC signals may be desirable in applications in which two or more electric circuits must communicate, but their grounds are at different potentials. Galvanically isolating the conductive coils may prevent accidental currents. For example, galvanic isolation may prevent current flowing through a person's body, even if the person physically contacts the secondary portion of the magnetic isolator. Magnetic isolator 100 may be configured to operate at voltages equal to or greater than 600V, equal to or greater than 900V, equal to or greater than 1200V, equal to or greater than 1500V, or equal to or greater than 1800V.

Conductive coil 106 may comprise an outermost portion 110, which may correspond to at least a portion of the outer periphery of the top conductive coil. Conductive coil 106 may be configured to limit the magnitude of the peak electric field in a region 115 near the outer edge of the conductive coil. Applicant has appreciated that regions of the dielectric layer near the outer edge of a conductive coil exhibit electric fields that are greater than in other regions of a magnetic isolator. This may be due in part to the outer edge not being bounded on both sides by another conductive portion of the conductive coil at the same potential. By contrast, inner portions of the conductive coil may be shielded by neighboring portions of the conductive coil at approximately equal potential, thus preventing undesirably high electric fields near those inner portions. Thus, outer regions of the conductive coil may be particularly susceptible to electric breakdown. To limit the magnitude of the peak electric field, outermost portion 110 may comprise a stepped portion, a Z-shaped portion, an L-shaped portion, a C-shaped portion, stair-like (or stair step) shaped portion, or other configurations comprising a non-planar portion, as can be seen in FIG. 1A.

FIG. 1B illustrates an example of an outermost portion 110 of the conductive coil 106 of FIG. 1A, according to some non-limiting embodiments. Outermost portion 110 may comprise lateral segment 142, lateral segment 144, and segment 148. As illustrated, outermost portion 110 may be disposed on dielectric layer 104.

The lateral segments may be offset with respect to each other along the x-direction. Lateral segments 142 and 144 may be connected to each other by segment 148, and may be offset from one another along the x-axis. It can be seen that while segments 142 and 144 are offset from each other along the x-axis, in some embodiments there may be some overlap of those segments in the lateral direction (the x-direction). In some embodiments, lateral segment 144 may be disposed on dielectric ridge 140. Dielectric ridge 140 may comprise the same material as dielectric layer 104, though the application is not limited in this respect. In some embodiments, outer edge 154 of lateral segment 144 may extend beyond outer edge 152 of lateral segment 142. In some embodiments, outer edge 152 may be closer to the center of conductive coil 106 than outer edge 154 along the x-axis. In some embodiments, bottom edge 164 of lateral segment 144 may extend beyond bottom edge 162 of lateral segment 142. In some embodiments, bottom edge 162 may be closer to the bottom conductive coil 102 than bottom edge 164 along the y-axis. Bottom edge 162 and bottom edge 164 may collectively form a non-planar bottom surface of outermost portion 110.

While FIG. 1B illustrates a dielectric portion 140 being higher (along the y-axis) than lateral segment 142, the opposite configuration is also possible. In the latter configuration, lateral portions 142 and 144 may partially overlap with each other along the x-axis. In some embodiments, outermost portion 110 may comprise a curved structure, such that the outer edge of the outermost portion 110 is curved. According to one aspect of the present application, the peak electric field arising in a region near outermost portion 110 may be lower than the peak electric field that would arise if outermost portion 110 was replaced with a planar portion (e.g., a portion having a rectangular cross section just like the illustrated inner portions of the conductive coil 106).

Referring back to FIG. 1A, conductive coil 106 may be connected to pad 120. Pad 120 may comprise a conductive material, and may be disposed within conductive coil 106 in some embodiments. Pad 120 may be bonded to a wire 122. In this way, conductive coil 106 may be electrically coupled to a device disposed outside substrate 101.

Bottom conductive coil 102 may be formed as a metallization layer on a surface of the substrate. Conductive coil 102 may comprise one or more loops, and may be shaped as a spiral, or may have any other suitable configuration. In some embodiments, the loops may be connected to each other, thus forming a continuous winding. Conductive coil 102 may comprise any suitable conductive material, such as aluminum, copper, gold, silver, or chromium. Conductive coil 102 may be connected to a pad 132. Pad 132 may comprise a conductive material, and may be exposed by forming of an opening on a surface of the substrate. Pad 132 may be bonded to a wire 134. In this way, conductive coil 102 may be electrically coupled to a device disposed outside substrate 101. Conducive coil 102 may be connected to pad 132 through metal wiring (or traces) 130. Metal wiring 130 may be connected to conductive coil 102 through one or more vias.

Dielectric layer 104 may be disposed on substrate 101, and may cover, at least partially, conductive coil 102. Dielectric layer 104 may comprise one or more materials having a large electric breakdown (e.g., greater than 100 KV/mm, greater than 500 KV/mm, greater than 1000 KV/mm, greater than 2000 KV/mm, greater than 3000 KV/mm, greater than 4000 KV/mm, between 2000 KV/mm and 5000 KV/mm or between any suitable range within such range). In some embodiments, dielectric layer 104 may comprise polyimide. In some embodiments, dielectric layer 104 may comprise more than one layer of dielectric material. In this way, if one of the dielectric layers experiences electrical breakdown, the presence of additional layers may mitigate the probability of forming a conductive path between the top conductive coil and the bottom conductive coil. Such multiple dielectric layers may be made from the same material (e.g., polyimide), or from different materials.

Alternatively, the bottom conductive coil of a magnetic isolator may be formed on a surface of a dielectric layer. Magnetic isolator 180, which is illustrated in FIG. 1C, may comprise a top conductive coil, dielectric layer 104, a bottom conductive coil, dielectric layer 105, and substrate 101. In some embodiments, dielectric layers 104 and 105 may be formed from the same dielectric material, such as polyimide. However, different dielectric materials may be used in other embodiments. In some embodiments, the bottom conductive coil may be formed from two conductive layers, though any other suitable number of conductive layers may be used. In some embodiments, the lower conductive layer of the bottom conductive coil comprises titanium tungsten. In some embodiments, the upped conductive layer of the bottom conductive coil comprises gold. The outermost portion of the bottom conductive coil may comprise segments 173 and 174. Segment 173 may extend outwardly from the outer edge 175 of segment 174. The use of segment 173 may reduce the peak electric field near the outermost portion of the bottom conductive coil. In some embodiments, both the top and the bottom conductive coils may have multi segmented outermost portions as illustrated in FIG. 1C. In other embodiments, only one conductive coil (either the top or the bottom conductive coil) may have multi segmented outermost portions. Thus, it should be appreciated that magnetic isolators according to aspects of the present application may include a top coil with a structure of the types described herein to reduce peak electric field, a bottom coil with a structure of the types described herein to reduce peak electric field, or both top and bottom coils with structures of the types described herein to reduce peak electric field. Stated another way, the configurations of top coils described herein may be applied to bottom coils as well. In some embodiments, the top conductive coil may be formed using a bottom conductive layer 161 and a top conductive layer 162. The bottom conductive layer may comprise titanium tungsten in some embodiments. The top conductive layer may comprise gold in some embodiments.

FIG. 1D is a top view illustrating top conductive coil 106 according to an embodiment of the present application. As illustrated, conductive coil 106 may comprise an outermost portion 110, which may represent the outer periphery of the conductive coil. That is, in the illustrated example the conductive coil is a spiral, and the outermost portion 110 is the largest loop of the spiral. Outermost portion 110 may comprise a lateral segment (e.g., lateral portion 144) in a different plane than the remainder of conductive coil 106. For example, a lateral segment positioned further from the underlying substrate than the other portions of the conductive coil may be provided, as shown in FIGS. 1A-1B.

According to one aspect of the present application, the probability of electric breakdown in the dielectric layer may be reduced by moving the location of the peak electric field nearer bottom conductive coil 102, and by shielding bottom conductive coil 102 with a material having a dielectric constant greater than that of dielectric layer 104. In this way, the peak electric field may be reduced by the high-dielectric constant material, thus resulting in an attenuation of its magnitude.

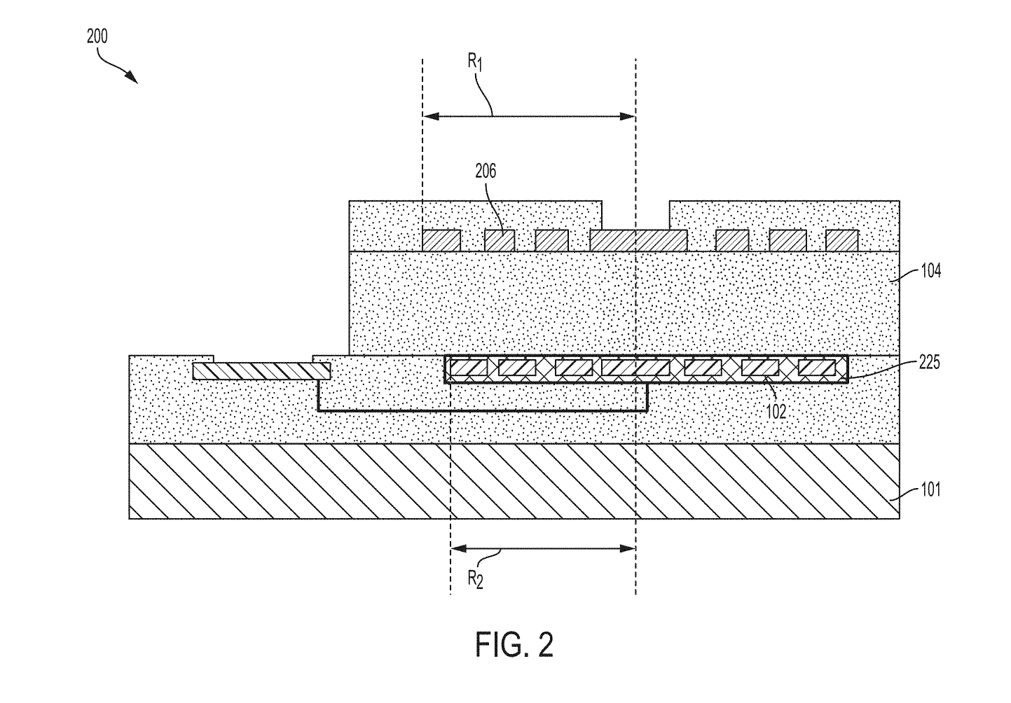

FIG. 2 illustrates a magnetic isolator 200 having a dielectric layer 225, a bottom conductive coil 102, a top conductive coil 206 and a dielectric layer 104. Dielectric layer 225 may have a higher dielectric constant than dielectric layer 104, and may contain at least a portion of bottom conductive coil 102 within its boundaries. In some embodiments, dielectric layer 225 may comprise silicon nitride.

To move the peak electric field away from top conductive coil 206, that coil may have a radius R₁ greater than the radius R₂ of bottom conductive coil 102. While not shown in FIG. 2, magnetic isolator 200 may comprise an outermost portion of the type described in connection with FIGS. 1A-1C. Thus, according to an aspect of the present application a magnetic isolator includes first and second coils, where one of the two coils has a larger radius than the other coil, and wherein one of the two coils has an outermost portion that is a stair step shape, like that shows in FIGS. 1A and 1B. In some embodiments, the same coil has the larger radius also has the outermost portion with a stair step shape.

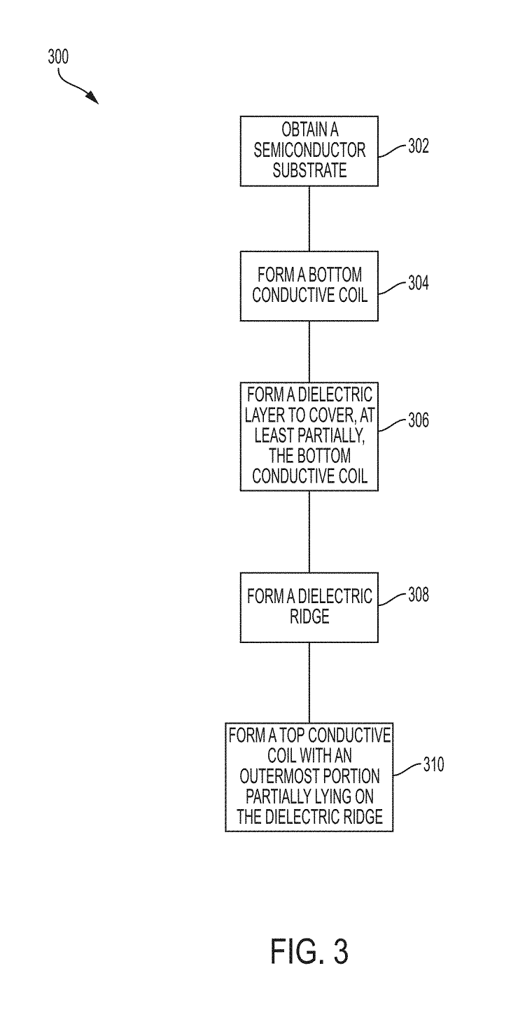

In some embodiments, magnetic isolators of the types described herein may be microfabricated using semiconductor fabrication techniques. FIG. 3 is a flowchart illustrating a method 300 for microfabricating a magnetic isolator of the type described herein, according to some non-limiting embodiments. At act 302, a semiconductor substrate may be obtained. In some embodiments, the semiconductor substrate may comprise silicon. At act 304, a bottom conductive coil may be formed on the semiconductor substrate. In some embodiments, the bottom conductive coil may be formed by creating a metallization layer on a surface of the semiconductor substrate, and by patterning the metallization layer to obtain the desired shape. At act 306, a dielectric layer may be deposited on the semiconductor substrate. The dielectric layer may comprise polyimide in some embodiments. The dielectric layer may cover, at least partially, the bottom conductive coil. At act 308, a dielectric ridge may be formed on the dielectric layer. The dielectric ridge may have a curved shaped, at least in some of its portions. In some embodiments, the dielectric ridge may be shaped to form a circle, or at least a portion of a circle. At act 310, a top conductive coil may be formed on the dielectric layer. In some embodiments, the top conductive coil may be formed by creating a metallization layer on a surface of the dielectric layer, and by patterning the metallization layer to obtain the desired shape. The top conductive coil may comprise an outermost portion lying, at least in part, on the dielectric ridge.

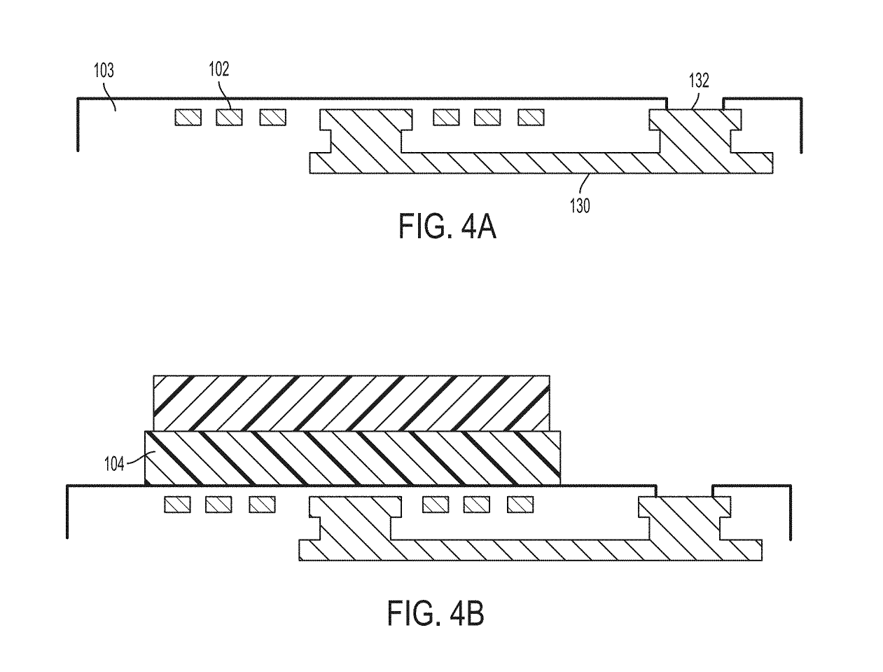

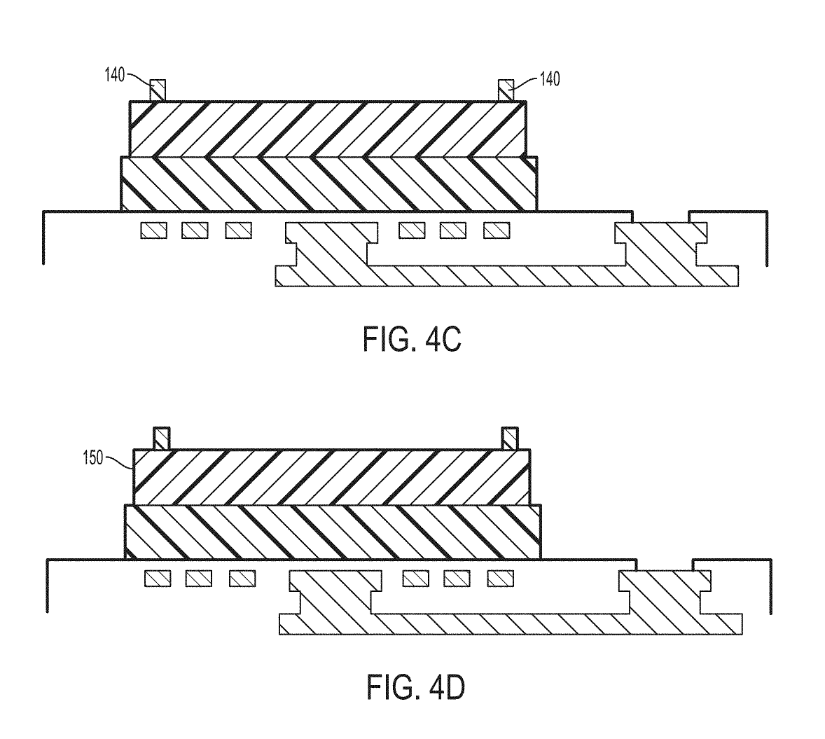

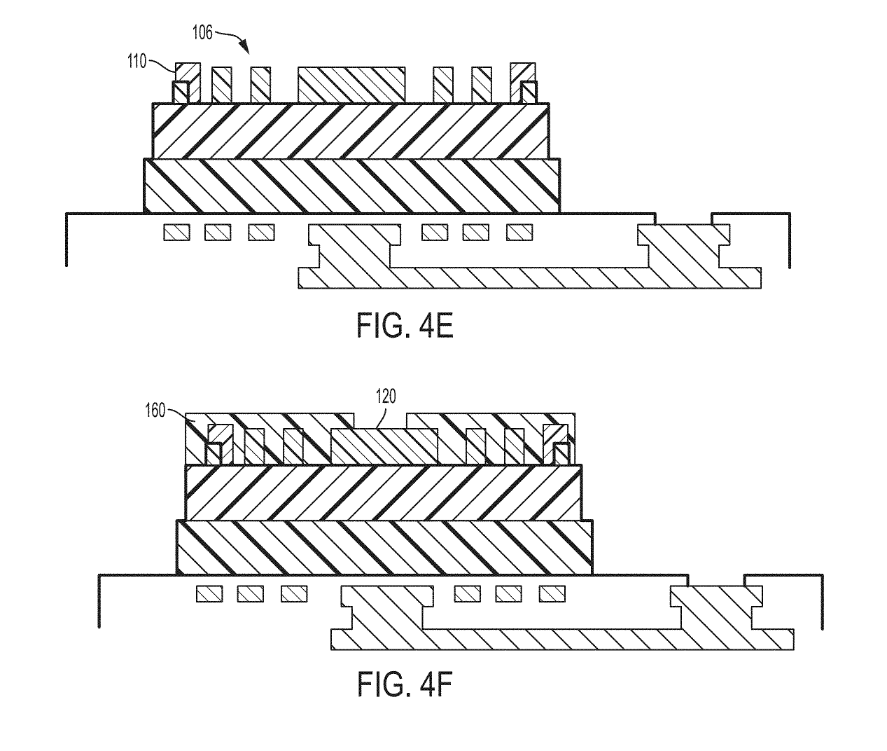

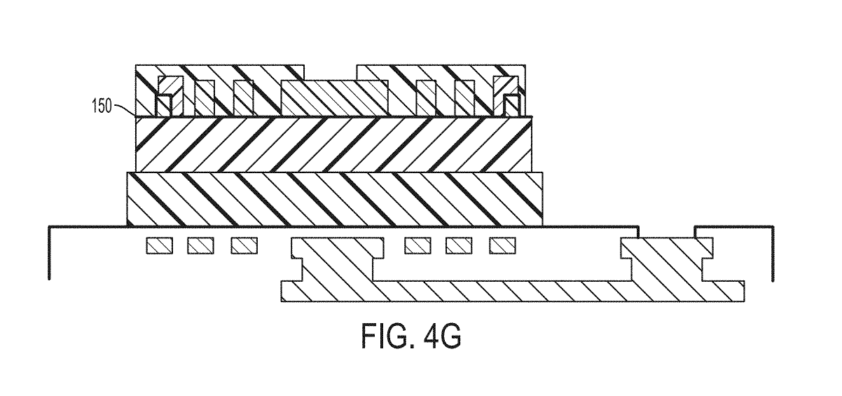

FIGS. 4A-4G are cross sectional views illustrating a non-limiting example of a method for microfabricating a magnetic isolator of the type described herein. In the process step illustrated in FIG. 4A, a dielectric material 103 may be disposed on substrate 101 (not shown in FIG. 4A). Dielectric material 103 may comprise silicon oxide in some embodiments. Bottom conductive coil 102, metal wiring 130 and pad 132 may be formed using photolithographic techniques. To provide access to the pad from an external circuit, an opening may be formed in dielectric material 103 in correspondence with pad 132.

In the process step illustrated in FIG. 4B, dielectric layer 104 may be formed on substrate 101 to cover, at least partially, conductive coil 102. Dielectric layer 104 may be comprise multiple dielectric materials in some embodiments, and may be formed using any suitable deposition technique, such as physical vapor deposition (PVD) or spin coating.

In the process step illustrated in FIG. 4C, dielectric ridge 140 may be formed. Dielectric ridge 140 may be formed by depositing a layer of dielectric material (e.g., polyimide), and by patterning the dielectric material to obtained the desired shape.

In the process step illustrated in FIG. 4D, a layer of dielectric material 150 may be deposited on dielectric layer 104. Such a dielectric material may have a greater dielectric constant than dielectric material 104. The use of dielectric material 150 may improve the endurance of the device with respect to the application of short voltages spikes. In some embodiments, dielectric material 150 may comprise silicon nitride.

In the process step illustrated in FIG. 4E, top conductive coil 106 may be formed. In some embodiments, top conductive coil 106 may be formed by electroplating. The outermost portion of top conductive coil 106 may be formed in part on dielectric ridge 140, thus forming a plurality of segments as described in connection with FIG. 1B.

In the process step illustrated in FIG. 4F, a dielectric material 160 may be formed to cover top dielectric coil 106. Dielectric material 160 may comprise polyimide or silicon oxide. An opening may be formed in dielectric material 160 in correspondence with pad 120.

In the process step illustrated in FIG. 4G, dielectric material 150 may be removed in regions not covered by dielectric layer 104. Dielectric material 150 may be removed using etching techniques.

In the embodiments illustrated in FIGS. 1A-1C, dielectric ridge 140 may be formed on a surface of dielectric layer 104. Furthermore, the outermost portion 110 may be partially formed on dielectric ridge 140. As a result, the outermost portion of the top conductive coil may exhibit a multi-segment configuration. As described above, such a configuration may limit the peak electric field. In other embodiments, a dielectric layer may be formed between the dielectric ridge and the top conductive coil. In this way, the top conductive coil may be formed on a smoother surface (e.g., a continuous surface without discontinuities in the area where the outermost portion is formed) compared with the embodiments illustrated in FIGS. 1A-1C.

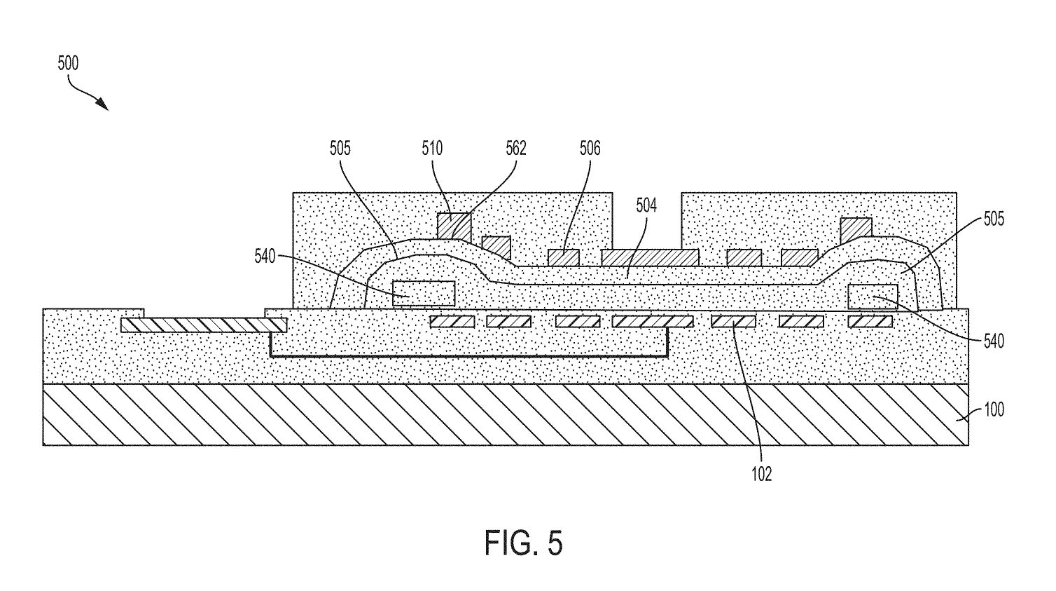

FIG. 5 is a cross sectional view of a magnetic isolator, according to some non-limiting embodiments. Magnetic isolator 500 may comprise substrate 100, bottom conductive coil 102, dielectric ridge 540, dielectric layer 504, and top conductive coil 506. The dielectric ridge 540 may be formed using polyimide in some embodiments, though other materials may be used. In some embodiments, the dielectric ridge may have a curved shaped, at least in some of its portions. In some embodiments, the dielectric ridge may be shaped to form a circle, or at least a portion of a circle. In some embodiments, the dielectric ridge may be formed on a surface of substrate 100. For example, the dielectric ridge may be formed after the bottom conductive coil 102 has been formed. Dielectric layer 504 may cover, at least partially, dielectric ridge 540. Dielectric layer 504 may comprise polyimide in some embodiments, though other materials may be used. In some embodiments, dielectric layer 504 may comprise more than one layer of dielectric material. In this way, if one of the dielectric layers experiences electrical breakdown, the presence of additional layers may mitigate the probability of forming a conductive path between the top conductive coil and the bottom conductive coil. Such multiple dielectric layers may be made from the same material (e.g., polyimide), or from different materials.

Dielectric layer 504 may exhibit a raised portion 505 in the region that sits over dielectric ridge 540. Such a raised portion may exhibit a smoother profile compared to dielectric ridge 540. Top conductive coil 506 may be formed on dielectric layer 504, such that outermost portion 510 sits, at least partially, on the raised portion 505. In this way, outermost portion 510 may exhibit a non-planar bottom surface 562. Compared to a case in which the top conductive coil is formed on a planar surface, the peak electric field may be limited in this configuration. Furthermore, compared to the embodiments illustrated in FIGS. 1A-1C, weakening of the isolation strength of dielectric material 504 may be limited. Accordingly, in contrast to the embodiments of FIG. 2C, in which the dielectric layer 104 may be exposed to a photolithographic process during the formation of dielectric ridge 140, when the outermost portion is formed using the configuration described in connection with FIG. 5, the dielectric layer 504 may not be exposed. When the dielectric layer is not exposed, its isolation strength may be preserved.

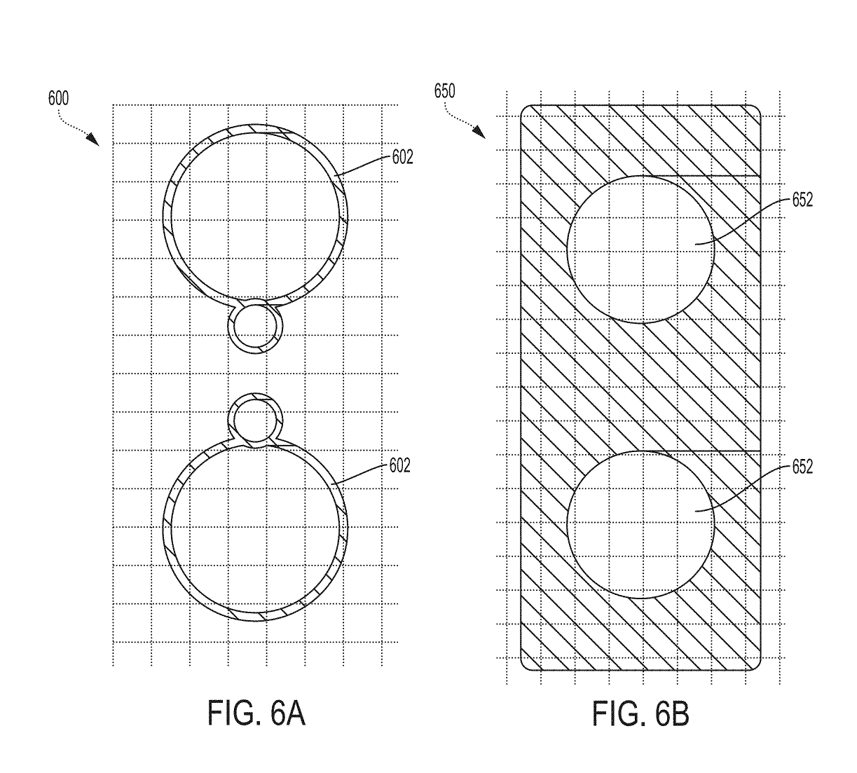

Dielectric ridge 540 may be formed lithographically using a photomask. Accordingly, a photomask may be used in a lithographic process step to selectively illuminate a region to be removed (or to selectively illuminate a region not to be removed). In some embodiments, photomask 600, illustrated in FIG. 6A, may be used to form a dielectric ridge. The photomask 600 may comprise contour 602. Contour 602 may have one or more rings in some embodiments. When a lithographic process step is performed using photomask 600, regions corresponding to contour 602 may not be illuminated. As a result, the dielectric ridge may be formed in the regions defined by contour 602.

Alternatively, a dielectric ridge may be formed lithographically using photomask 650, which is illustrated in FIG. 6B. Photomask 650 may comprise apertures 652. The apertures may have circular shapes in some embodiments. When a lithographic process step is performed using photomask 650, regions corresponding to aperture 652 may not be illuminated. As a result, the dielectric ridge may be formed in the regions outside apertures 652.

A magnetic isolator of the types described herein may be deployed in various settings to galvanically isolate one portion of an electric circuit from another. One such setting is in industrial applications. In some embodiments, a magnetic isolator may isolate a motor driver from other portions of an electric system. The motor driver may operate at voltages equal to or greater than 600V in some embodiments, and may comprise an inverter to convert a DC signal to an AC signal. In some embodiments, the motor driver may comprise one or more insulated gate bipolar transistors (IGBT), and may drive an electric motor according to a three-phase configuration.

Another such setting is in photovoltaic systems. In some embodiments, a magnetic isolator may be installed in a photovoltaic system to isolate a photovoltaic panel and/or an inverter from other parts of the system. In some embodiments, a magnetic isolator may be installed between a photovoltaic panel and an inverter.

Another such setting is in electric vehicles. In some embodiments, a magnetic isolator of the type described herein may be used to isolate any suitable part of an electric vehicle, such as a battery or a motor driver, from other parts of the vehicle.

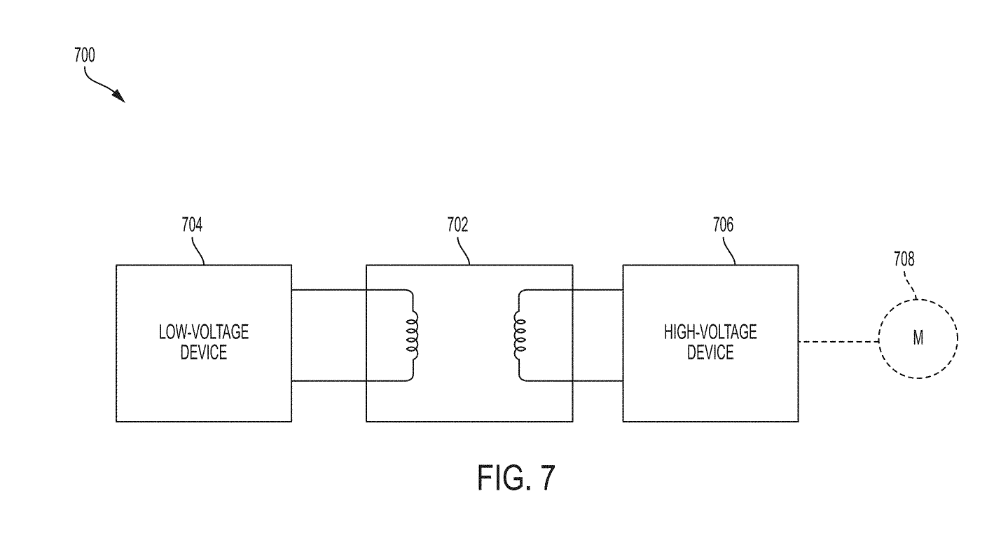

FIG. 7 is a block diagram illustrating an example of a system comprising a magnetic isolator of the type described here. System 700 may comprise magnetic isolator 702, low-voltage device 704, and high-voltage device 706. In some embodiments, low-voltage device 704 may comprise a conductive part. In some embodiments, low-voltage device 704 may comprise a device operating at less than 500V. In some embodiments, high-voltage device 706 may comprise a device operating at 500V or higher.

Magnetic isolator 702 may be implemented using magnetic isolator 100, 180, 200 or 500, and may be disposed between the low-voltage device and the high-voltage device. By isolating the two devices from one another, a user may be able to physically contact the low-voltage device without being electrically shocked or harmed. Low-voltage device 704 may comprise a user interface unit, such as a computer or other types of terminals, and/or a communication interface, such as a cable, an antenna or an electronic transceiver. High-voltage device 706 may comprise a motor driver, an inverter, a battery, a photovoltaic panel, or any other suitable device operating at 500V or higher. In the embodiments in which high-voltage device 706 comprises a motor driver, high-voltage device 706 may be connected to an electric motor 708.

Aspects of the present application may provide one or more benefits, some of which have been previously described. Now described are some non-limiting examples of such benefits. It should be appreciated that not all aspects and embodiments necessarily provide all of the benefits now described. Further, it should be appreciated that aspects of the present application may provide additional benefits to those now described.

Aspects of the present application provide a magnetic isolator capable of withstanding voltages exceeding 600V while limiting the probability of electric breakdown. As a result of such a reduction in the probability of electric breakdown, the lifetime of the magnetic isolator may be extended.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. An apparatus comprising:
a first conductive coil;
a second conductive coil; and
a dielectric layer separating the first conductive coil from the second conductive coil;
wherein the first conductive coil comprises an outermost portion having a non-planar bottom surface.

2. The apparatus of claim 1, wherein the outermost portion comprises a first lateral segment and a second lateral segment connected to the first lateral segment and laterally offset from the first lateral segment.

3. The apparatus of claim 2, wherein at least a portion of the first lateral segment is closer to a center of the first conductive coil than the second lateral segment.

4. The apparatus of claim 3, wherein the first lateral segment is closer to the second conductive coil than the second lateral segment.

5. The apparatus of claim 1, wherein the outermost portion of the first conductive coil sits at least in part on a raised portion of the dielectric layer.

6. The apparatus of claim 5, wherein the raised portion of the dielectric layer is formed on a dielectric ridge.

7. The apparatus of claim 1, wherein the first conductive coil has a first radius and the second conductive coil has a second radius, and wherein the second radius is less than the first radius.

8. The apparatus of claim 1, wherein the dielectric layer is a first dielectric layer and has a first dielectric constant, and wherein the second conductive coil is encased in a second dielectric layer having a second dielectric constant, wherein the second dielectric constant is greater than the first dielectric constant.

9. The apparatus of claim 1, wherein the first conductive coil is a spiral.

10. The apparatus of claim 1, wherein the first conductive coil and the second conductive coils are disposed on a semiconductor substrate.

11. An apparatus comprising:
a first conductive coil;
a second conductive coil;
a dielectric layer separating the first conductive coil from the second conductive coil; and
a controller electrically coupled to the first conductive coil;
wherein the first conductive coil comprises an outermost portion having a non-planar bottom surface.

12. The apparatus of claim 11, wherein the outermost portion comprises a first lateral segment and a second lateral segment connected to the first lateral segment and laterally offset from the first lateral segment.

13. The apparatus of claim 12, wherein at least a portion of the first lateral segment is closer to a center of the first conductive coil than the second lateral segment.

14. The apparatus of claim 13, wherein the first lateral segment is closer to the second conductive coil than the second lateral segment.

15. The apparatus of claim 11, wherein the controller comprises a motor driver.

16. The apparatus of claim 11, wherein the outermost portion of the first conductive coil sits at least in part on a raised portion of the dielectric layer.

17-20. (canceled)

21. An apparatus comprising:
a first conductive coil;
a second conductive coil; and
a dielectric layer separating the first conductive coil from the second conductive coil;
wherein the first conductive coil comprises an outermost portion having a plurality of laterally offset segments.

22. The apparatus of claim 21, wherein the plurality of laterally offset segments are arranged in a stair step configuration.

23. The apparatus of claim 21, wherein at least one segment of the plurality of laterally offset segments sits, at least in part, on a dielectric ridge.

24. The apparatus of claim 21, wherein the first conductive coil has a first radius and the second conductive coil has a second radius, and wherein the second radius is less than the first radius.
